(19) United States
(12) Patent Application Publication
(10) Pub. No.: US 2006/0233692 A1
(43) Pub. Date: Oct. 19, 2006

(54) Nanotube/metal substrate composites and methods for producing such composites

(75) Inventors: Robert P. Scaringe, Rockledge, FL (US); Dwight D. Back, Pembroke Pines, FL (US); John A. Meyer, Palm Bay, FL (US); Russell W. Davis, Melbourne, FL (US); Gregory S. Cole, Melbourne, FL (US)

Correspondence Address: CROWELL & MORING LLP;INTELLECTUAL PROPERTY GROUP, P.O. BOX 14300, WASHINGTON, DC, 20044-4300, US

(73) Assignee: Mainstream Engineering Corp., Rockledge, FL (US)

(21) Appl. No.: 11/258,918

(22) Filed: Oct. 27, 2005

Related U.S. Application Data
(63) Continuation-in-part of application No. 10/831,157, filed on Apr. 26, 2004.

(51) Int. Cl. D01F 9/12; C23C 16/00; B05D 3/00; B05D 7/00

(52) U.S. Cl. 423/335; 423/447.3; 423/561.1; 427/248.1; 427/402; 427/299; 427/331

(57) ABSTRACT

Carbon nanotubes are grown directly on metal substrates using chemical vapor deposition. Metal substrates are comprised of catalysts which facilitate or promote the growth of carbon nanotubes. The nanotube coated metal substrates have applications including, but not limited to, heat transfer and thermal control, hydrogen storage, fuel cell catalytic reformers, electronics and semiconductors, implantable medical devices or prostheses, and tribological wear and protective coatings.

### CROSS-REFERENCE

This application incorporates by reference application Ser. No. 10/898,933, filed Jul. 27, 2004.

### BACKGROUND OF THE INVENTION

One of the most significant spin-off products of fullerene research, which lead to the discovery of the C60 “buckyball” by the 1996 Nobel Prize laureates Curl, Kroto, and Smalley, are nanotubes based on carbon or other elements. Carbon nanotubes are fullerene-related structures which consist of graphene cylinders closed at either end with caps containing pentagonal rings. A carbon nanotube is essentially a seamless honeycomb graphite lattice rolled into a cylinder. The single-walled nanotube (SWNT) diameter is about 1-3 nm, with lengths of 100's to 1000's nanometers. The multi-walled nanotube is comprised of about 10-100 concentric tubes with an internal diameter of about 1-10 nm and an outer diameter of up to about 50 nm. The density of carbon nanotubes is about 1.3-1.4 g/cm³ and the surface areas are typically on the order of 103 m²/g.

Carbon nanotubes (CNT's) have been demonstrated for use in various electronic and chemical-mechanical devices functional on the molecular scale used alone or in combination with other materials. With regard to electronics applications, carbon nanotubes can function as either a conductor or semiconductor, depending on the rolled shape and the diameter of the helical tubes. Among these devices are chemical force sensors, field emission displays, molecular wires, diodes, FET's, single-electron transistors, and rechargeable batteries. CNT's have also shown great promise for gas storage (e.g., hydrogen) and in fuel cells. With regard to thermal and energy applications nanotubes can be used, for example for hydrogen storage, fuel cells and catalytic reformers for fuel cells, heat sinks, heat pipes, and other heat transfer or exchange devices.

Certain metals are already known to catalyze the growth of carbon nanotubes. These catalysts include Fe, Mo, Ni, Y, and Co and are typically deposited onto a support such as alumina and silica which requires a separation step before the nanotubes can be deposited or combined with other substrates.

There are several methods currently employed to produce nanotubes. Carbon nanotubes have been produced by an arc discharge between two graphite rods. Another method produces carbon nanotubes at high temperatures by irradiating a laser onto graphite or silicon carbide. Yet another method involved chemical vapor deposition (CVD) and plasma CVD. Catalyzed CVD is probably the most practical method for the production of carbon nanotubes. CVD is scalable and compatible with integrated circuit and MEMS manufacturing processes. CVD allows high specificity of single wall or multi wall nanotubes through appropriate selection of process gasses. Carbon feedstock comes from the decomposition of a feed gas such as methane or ethylene. Other hydrocarbon feeds such as acetylene, carbon monoxide, methanol, ethanol, toluene, xylene or benzene have also been used with the understanding that they have been used successfully.

Single-walled nanotubes (SWNT) or multi-walled nanotubes (MWNT) are typically grown on substrates which contain catalysts to promote their growth. Typical substrates, or support materials, are silica and alumina. In most applications these high surface area substrates are used to disperse the catalysts in high concentrations. These growth support materials and catalysts are then typically separated from the nanotubes before the nanotubes can be used in any application. One method to separate the nanotubes from the support material is acid or base digestion. This digestion process can sometimes decompose or alter the nanotubes, and can be time-intensive and expensive. In many current applications the purified nanotubes must then be attached in some way to a substrate.

The formation and growth of carbon nanotubes are facilitated by many metals and their oxides. These catalysts function by dissolving the carbon and then re-precipitating it into tubes and other nanoscale carbon structures. This process is best facilitated by metals which form solid solutions with the carbon such as Al, Be, Co, Cr, Fe, Hf, Ir, Mn, Mo, Nb, Ni, Os, Pb, Pd, Pt, Rh, Ru, Sb, Ta, Ti, V, Y, and Zr and oxides thereof

The most common metals currently used in the art to produce carbon nanotubes include Fe, Mo, Ni, Y, Zn, Ru, and Co. The difficulty with state-of-the-art nanotube production processes is that the metals must first be deposited on a high surface area support such as alumina or silica, which must be dissolved to separate the nanotubes. Nanotubes have also been grown on islands of metal catalysts deposited onto silicon and silicon oxide substrates but this requires a separate metal deposition process and sometimes lithographic processes. One common method to produce these islands is to deposit a solution containing the catalysts on a surface, and then subjects the substrate and deposited catalyst to the CVD process. The nanotubes are deposited on the surface but are not always integrated into the structure of the substrate or directly connected to the surface. Another method that has been employed is to sputter catalytic metals onto a substrate prior to nanotube growth.

A CVD process which directly grows carbon nanotubes on a metal surface would have tremendous benefit to many applications. This eliminates the need to perform separation of the nanotubes from the catalyst and support, does not require a metal deposition step onto a substrate, utilizes metals and alloys already available commercially, does not require a separate attachment step of the nanotubes to the substrate, is amenable to large scale continuous processes, and provides for better contact between the substrate and the nanotubes. Better contact between the nanotubes and substrate will have advantages in electrical and thermal properties.

U.S. Pat. Nos. 6,522,055 and 6,652,923 teach an electron emitting source produced by deposited nanotubes on iron substrates in which metal and metal alloys comprised of Fe, Ni and Co are used to grow nanotubes. However, this approach did not recognize the advantages of using copper-based substrates with these and other metals to promote nanotube growth while at the same time maximizing thermal and electrical conductivity by using high thermally and electrically conductive materials. High thermal conductivities and low internal resistances are preferred for electronic and thermal control devices. The importance of metal grain size for growing single walled nanotubes, or the advantages of using nanotube coated alloys for ultracapacitors, batteries, hydrogen storage, and heat transfer devices was also not recognized. Nor did the prior art recognize that cleaning preparation of the metal substrates is important to providing a reactive nanotube growth site.

### SUMMARY OF THE INVENTION

The present invention teaches a method and apparatus to prepare carbon nanotubes on metal substrate in a greatly simplified and advantageous manner for lower cost production of such composites. According to the present invention, carbon nanotubes (SWNT's or MWNT's) can be grown directly on metal substrates to produce metal-carbon nanotube composites. Our invention teaches a method for preparing the metal substrates and for growing nanotubes directly on the surface using chemical vapor deposition (CVD). Other nanotube growth processes such as laser vaporization can also utilize this technique and are contemplated as being within the scope of our invention.

Our invention is based upon the discovery that nanotubes can be grown directly onto metal substrates containing these catalysts which eliminates the need to separate the nanotubes prior to deposition or to combine the nanotubes with other substrates used in an application. Our method does not require the use of other support materials such as alumina or silica which are commonly used. This method also does not require the deposition of metal catalysts by solution or other means (e.g., plasma or ion implantation). Furthermore, the growth of carbon nanotubes directly onto metal substrates provides a production cost reduction since no additional materials (e.g., catalysts, supports, and digestion media) are needed.

One key aspect of this invention is a recognition of the importance of the selection of metals and a surface morphology with metal grain boundaries small enough to grow nanotubes. The diameter of nanotubes is directly related to the size of the metal catalyst grains, and we have taken advantage of the fact that metals comprising alloys are present in small grain structures on the surface of most metal alloys. Many of the alloys within the scope of this invention have individual metal grain sizes of nanometer scale on the surface of the material to facilitate growth of SWNT's and MWNT's. The SWNT's or MWNT's can also be perpendicularly aligned to the metal alloy surface.

In order for a metal to facilitate carbon nanotube growth, carbon must form solid solutions with the metal at typical CVD nanotube growth temperatures (approx. 500 C to 1200 C). Based on our aforesaid recognition, we have now been able to identify metals which are suitable for this process through analysis of carbon-metal phase diagrams. These metals include, but are not limited to: Al, Be, Co, Cr, Fe, Hf, Ir, Mn, Mo, Nb, Ni, Os, Pb, Pd, Pt, Rh, Ru, Sb, Ti, V, Y, and Zr. Other transition metals can also promote nanotube growth.

We have successfully grown carbon nanotubes on several metal alloys which contain these catalytic metals. After pickling these metals (e.g., with inorganic acids), we have found that it is possible to grow nanotubes directly on the surface of the metals surface. For example, we have discovered that metal alloys such as CDA 704 (91% Cu, ˜1.5% Fe, ˜5.5% Ni), CDA 706 (88% Cu, ˜1.5% Fe, ˜10% Ni), Hastelloy G-30 (43% Ni, ˜30% Cr, ˜15% Fe, ˜5% Mo), Incoloy MA 956 (74% Fe, 5% Al, 20% Cr, 0.5% Y2O3), and Hastelloy C-276 (57% Ni, ˜16% Cr, ˜6% Fe, 16% Mo) provide for direct surface growth of nanotubes on their surface. We have also grown carbon nanotubes on the surface of metal alloys typically used for hydrogen storage. There are numerous other alloys which contain metals known to catalyze and/or promote the growth of nanotubes. Preferred metal alloy constituents of this invention include Al, Co, Cr, Fe, Ir, Mn, Mo, Nb, Ni, Os, Pb, Pd, Pt, Rh, Ru, Sb, Ta, Ti, V, Y, and Zr. Metal oxides of these metals are also catalysts. We have discovered that these alloys can also be oxidized and used as a nanotube growth substrate.

Applications for nanotube-coated metals include various electronic and chemical-mechanical devices functional on the molecular scale used alone or in combination with other materials. With regard to electronics applications, carbon nanotube coated metals can function as either a conductor or semiconductor, depending on the rolled shape and the diameter of the helical tubes. Among these devices, but not limited thereto, are chemical sensors, field emission displays, molecular wires, diodes, FET's, single-electron transistors, ultracapacitors and rechargeable batteries.

We have discovered benefits with regard to carbon nanotube coated electrodes used in batteries and ultracapacitors. In particular, we have found much higher than expected specific energy capacities for carbon nanotubes directly grown on metal substrates compared to solution-deposited carbon nanotubes. The method of our invention does not require purification, separation, or dispersion steps involving acids and sonication which can damage and poison the nanotubes, reducing their intercalation stoichiometric on the carbon electrode. Another unexpected discovery of this invention is that the carbon nanotubes deposited as described herein do not need to be 100% pure on the surface of the metal substrate to achieve the surprising benefits in specific energy capacity. The deposited carbon coating on the metal substrate will contain varying quantities of SWNT's, MWNT's, “bucky onions,” and other ordered carbon structures, as well as amorphous carbon, depending on the specific CVD production parameters (e.g., gases, temperatures, and times) used. Whereas the prior art has focused intensely on purifying the carbon nanotubes prior to solution-depositing onto a substrate, we have found that this purification step is unnecessary. Our invention thus provides additional benefits in producing carbon nanotube coated electrodes in a single-step process which is faster and less costly than those methods taught in the prior art.

Solution-deposited carbon nanotubes will also be difficult to align perpendicularly to a surface because these nanotubes were not grown from, or attached to, the metal substrate. Directly growing the nanotubes onto a battery or ultracapacitor electrode provides benefits with respect to electron flow and internal battery resistance since these is no discontinuity between the carbon nanotube and the metal substrate. Directly attached carbon nanotubes will also provide a benefit of extended life inasmuchas the coating will be less easily worn off compared to carbon nanotubes which are solution deposited. This unexpected benefit also has utility in the field of sensors which now preferably will not have to be made with nanotubes that will wear off or degrade with time.

CNT's have also shown great promise for gas storage (e.g., hydrogen) and in fuel cells. With regard to thermal applications we have also discovered that nanotube-coated substrates can be used in applications such as hydrogen storage, heat sinks, heat pipes, heat exchangers, spray cooling surfaces, and other heat transfer devices which function to exchange heat between a surface and a gas or liquid. In particular, we have discovered that the nanotube coated surfaces display improved single-phase and two-phase convective heat transfer characteristics making them ideal surface treatments for cold plates, heat exchangers, heat pipe surfaces and heat pipe wick materials, micro-channel cooling passages, and both liquid-jet and saturated spray-cooling surfaces. Nanotube coated surfaces also display reduced thermal interface resistance.

We have also discovered that there are unexpected and multiple benefits by enhancing a metal substrate surface with carbon nanotubes. Heat transfer between two phases (e.g., between a gas or liquid (“fluid”) and a solid surface) depends on a series of “resistances” including natural or forced convention heat transfer, and conduction through a material (e.g., the carbon nanotube coating an underlying metal substrate). In order to enhance the net heat transfer rate, all of these resistances must be altered; otherwise the limiting “resistance” will dictate the net heat transfer rate. For example, if the conductivity of heat through a coating is very low, yet the heat transfer rate to this coating surface from the bulk fluid is high, the net heat transfer rate will still be low and limited by the conductivity through the coating. Therefore, we attribute the improvements to heat transfer that we have discovered by the methods of this invention to enhancement in all of these resistances. The unexpected enhancements to heat transfer resulting from coating metal substrates with nanotubes can be attributed to increases in convective heat and mass transfer rates due to the alteration of he hydrodynamic boundary layer, increases in surface area, an increase in the number of nucleation sites and decrease of nucleation site size for boiling fluids, changes in surface tension as a result of the nanodimensions of the coating, the pumping action of nanotubes and nanotube networks on the surface, the intimate thermal contact of the nanotubes with the metal substrate, and the combination of high thermal conductivity metals with the carbon nanotubes.

Materials coated with carbon nanotubes may also possess superior tribological properties and frictional heating dissipation for use in mechanical parts, implantable medical devices, or prostheses. Using the methods taught by this invention, it is also contemplated that inorganic analogs of carbon nanotubes can be grown directly on metal substrates in a manner previously not deemed to be possible or practical.

One object of this invention is to provide a method for growing carbon nanotubes directly onto metal substrates.

Another object of this invention is to provide a method for coating metal surfaces with nanotubes without the need for support materials or catalysts which must be separated from the carbon nanotubes before using the carbon nanotubes.

Accordingly, still another object of this invention is to provide a way to coat metal substrates that eliminates the handling of carbon nanotube powder or dust which may be harmful to health and the environment.

Yet another object of this invention is to use metal alloy substrates, containing catalytic metal components, to grow nanotubes on their surface.

A further object of this invention is to provide a method to produce nanotube coated metal substrates which can be used for a wide variety of applications, including, but not limited to hydrogen storage, heat sinks, heat pipes, heat exchangers, wear coatings, single and two-phase heat transfer enhancements, batteries, ultracapacitors, fuel cells, catalytic reformers for fuel cells, solar collectors, chemical sensors, and medical devices, or prostheses.

One advantage of this invention is that certain alloys containing primarily copper, have superior thermal and electrical conductivity properties when nanotubes are grown directly on their surface from islands of metals that are known to promote and facilitate carbon nanotube growth.

A still further object of this invention is to provide a way to coat metal substrates for mass production of parts which can be used in a variety of commercial applications, including, but not limited to hydrogen storage, heat sinks, heat pipes, heat exchangers, wear coatings, single and two-phase heat transfer enhancements, batteries, fuel cells, catalytic reformers for fuel cells, ultracapacitors, solar collectors, chemical sensors, and medical devices, or prostheses.

### BRIEF DESCRIPTION OF THE DRAWINGS

Other objects, advantages and novel features of the present invention will become apparent from the following detailed description of the invention when considered in conjunction with the accompanying drawings.

FIG. 1 is a schematic cross-sectional view of a batch coating apparatus for carrying out a process using the method of the present invention;

FIG. 2 is a schematic cross-sectional view of continuous coating apparatus for carrying out a process using the method of the present invention;

FIG. 3 is a simplified schematic cross-sectional view of a metal-carbon nanotube-polymer composite of the present invention.

FIG. 4 is a perspective view of metal alloy coupons before and after coating with carbon in a CVD nanotube furnace;

FIG. 5 is a 35000×SEM image of nanotubes formed on the surface of a CDA-704 alloy;

FIG. 6 is a 35000×SEM image of nanotubes formed on the surface of an Incoloy MA 956 alloy;

FIG. 7 is a 3500×SEM image of nanotubes formed on the surface of a CDA-706 alloy;

FIG. 8 is a 35000×SEM image of nanotubes formed on the surface of a CDA-706 alloy;

FIG. 9 is an X-ray energy dispersive spectrophotometer image of a CDA 706 alloy;

FIG. 10 is an SEM image of a CDA 704 material coated with carbon nanotubes, after being ion milled and platinum coated;

FIG. 11 shows respectively a heat sink side view (A) and in top view (B).

FIG. 12 is a perspective view showing two different configurations of heat pipes;

FIG. 13 is a heat transfer curves for carbon nanotube coated coupons in vertical and horizontal configurations;

FIG. 14 is a graph showing the maximum temperature gradient as a function of the applied heat flux in a nanotube-coated heat pipe and an uncoated heat pipe;

FIG. 15 is a schematic cross-sectional view of a prior version of a lithium ion battery using carbon nanotube coated metal electrode; and

FIG. 15a is a schematic cross-sectional view of a newer version of lithium ion battery using carbon nanotube coated metal electrode, cathode and separator membrane; and

FIG. 16 is a graph showing the improvement in the total heat rejection capability for a natural convection finned heat sink (8 fin configuration) when a nanotube coating is applied to the heat sink surface

### DETAILED DESCRIPTION OF THE INVENTION

Certain metals are already known to catalyze the growth of carbon nanotubes. These catalysts include, but are not limited to Fe, Mo, Ni, Y, and Co and are typically deposited onto a support such as alumina and silica which requires a separation step before the nanotubes can be deposited or combined with other substrates.

Our invention is based upon the discovery that nanotubes can be grown directly onto metal substrates containing these catalysts which eliminate the need to separate the nanotubes prior to deposition or combination with other substrates used in an application. Our method does not require the use of other support materials such as alumina or silica which are commonly used. This method also does not require the deposition of metal catalysts by solution or other means (e.g., plasma or ion implantation). Furthermore, the growth of carbon nanotubes directly onto metal substrates provides a production cost reduction since no additional materials (e.g., catalysts, supports, and digestion media) are needed.

One way to grow nanotubes using the method of the present invention is by chemical vapor deposition (CVD). Other means known by those skilled in the art are contemplated as encompassing the methods of this invention such as plasma assisted CVD.

Metal alloys comprised of metals known to facilitate carbon nanotube growth are prepared by pickling (e.g., acid cleaning) or other cleaning procedures and placed in a CVD furnace. A pickling process removes contaminants and other materials on the surface of the metals which can be detrimental to nanotube growth. We have discovered that the cleaning process is an important step in the preparation of alloys to be coated with carbon nanotubes. One currently preferred embodiment of this invention uses a metal preparation process described in ASTM method G1-03, “Standard Practice for Preparing, Cleaning, and Evaluating Corrosion Test Specimens.” These methods typically utilize an acid treatment with solvent rinses.

After preparation and cleaning of the metal substrates, they are placed in a CVD furnace. Typical conditions used in CVD furnaces for nanotube growth are about 500-1200 C in the presence of carbon feedstock vapors including, but not limited to ethylene, methane, propane, carbon monoxide, acetylene, methanol, ethanol, xylene, toluene, and benzene. The preferred flow rates for these gases will depend on the size of the CVD furnace. One preferred embodiment of this invention uses ratios of methane to hydrogen of about 0.2 to 10, and ratios of ethylene to hydrogen of 0 to about 10. Hydrogen is used to vary the kinetics of the hydrocarbon feedstock composition and carbon nanotube formation reaction inasmuch as hydrogen is a product of carbon feedstock decomposition. The process also consists of a gas purge during cooling after the nanotubes have been formed on the substrates. Gases used for the cooling process are typically nitrogen or argon, or other inert gases. Carbon feedstock such as methanol and ethanol can also be used to grow purer SWNT's. Lower CVD temperatures (about 600-800 C) can be used with these feedstock materials with less amorphous carbon being produced in the process. Aligned nanotubes can also be grown on the metal alloy substrates using carbon feedstock such as ethanol, methanol, benzene, xylene, and toluene.

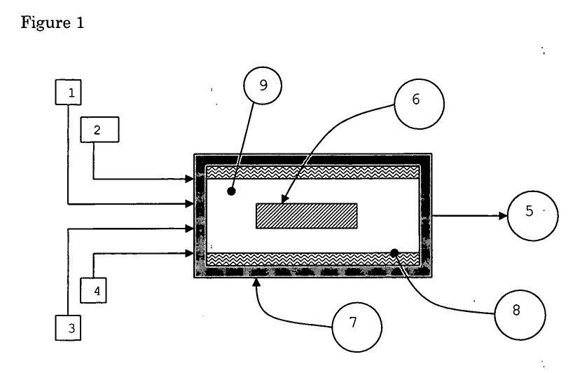

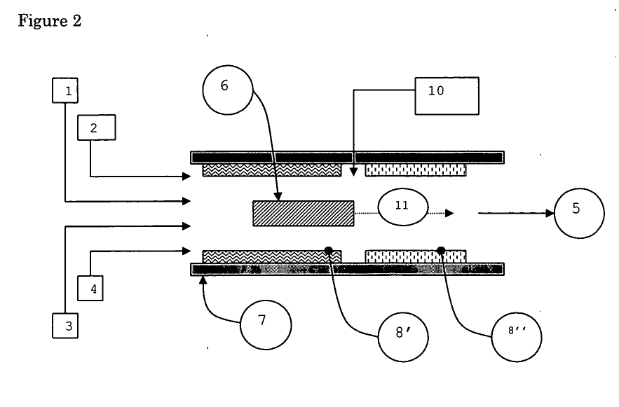

The coating process of the present invention can be implemented in a batch or continuous feed process. In fact, the present invention greatly simplifies the process by which large quantities of metal substrates can be coated for use in high volume commercial products such as batteries, ultracapacitors, heat exchangers, electronics, hydrogen storage, catalytic reformers for fuel cells, heat sinks, and heat pipes. Moreover, this process can be provided in the form of a batch or continuous process as illustrated by FIGS. 1 and 2. In those figures, carbon feedstock and purge gases designated by numerals 1-4 can be introduced into a furnace 9 heated by a heater 8 and provided with insulation 7, and exhausted through an exhaust port 5. The substrate 6 is subjected to the gases 1 through 4 at a temperature of about 500-1200° C. The gases 1 through 4 can be controlled by pressure and/or flow control devices, and the pressure in the furnace 9 can be sub-atmospheric, atmospheric or high pressure. In a continuous mode, the substrate can be conveyed through a furnace by a conveying device 11 with one or more heating zones defined spatially by heaters 8′ and 8″. Additional gases can be introduced (illustrated schematically by numeral 10) along its length so as to vary the environment in the chamber. For example, the substrate can be subjected to carbon feedstock gases in one zone at temperature T8′ (corresponding to heating zone and heater 8′), and then cooled with a purge gas at T8″(corresponding to heating zone and heater 8″) in a second zone.

The nanotube CVD growth process can last from about 10 minutes up to several hours. After growing the nanotubes on the metal substrates, the substrates can optionally be subjected to a heat treatment in air or oxygen at about 400-600° C. to oxidize amorphous carbon, thereby purifying the nanotube coating. Amorphous carbon will oxidize at around 400 to about 600° C., whereas nanotube carbon oxidizes above about 650° C. Optionally, the carbon coating on the metal alloy substrates can be purified by plasma etching the coated substrate with fluorinated gases, ammonia, oxygen or water. Vapors of ammonia and/or water may also be used during the CVD process to alter the morphology of the growth catalysts and/or to further enhance the growth of carbon nanotubes.

It was unexpected that copper containing alloys would promote nanotube growth since cooper is not known by those skilled in the art to facilitate nanotube growth. Hence, alloys containing copper have been perceived as being detrimental to nanotube growth. We discovered that the advantages of copper (e.g., high thermal conductivity and low electrical resistivity) can be utilized while at the same time facilitating the growth of nanotubes if certain other metal constituents are present and dispersed homogeneously in the alloy.

We have discovered that there are unexpected and multiple benefits by enhancing a metal substrate surface with carbon nanotubes. Heat transfer between two phases (e.g., between a gas or liquid (“fluid”) and a solid surface) depends on a series of “resistances” including natural or forced convention heat transfer, and conduction through a material (e.g., the carbon nanotube coating an underlying metal substrate). In order to enhance the net heat transfer rate, all of these resistances must be altered; otherwise the limiting “resistance” will dictate the net heat transfer rate. For example, if the conductivity of heat through a coating is very low, yet the heat transfer rate to this coating surface from the bulk fluid is high, the net heat transfer rate will still be low and limited by the conductivity through the coating. Therefore, we attribute the improvements to heat transfer that we have discovered by the methods of this invention to enhancement in all of these resistances. The scale of the nanotube structures on the surface are 10's-100's of nanometers. This nanoscale of surface roughness is not typically considered in the field of fluid mechanics and heat transfer, and therefore its benefits have not previously been appreciated.

The carbon nanotube coating surface is very porous and possesses a high surfaces area relative to the underlying metal substrate. Hence, the carbon nanotube coating will not only provide enhancement to the thermal conductivity resistance due to the intimate contact of the metal surface and the attached carbon nanotubes coupled with the known thermal conductivity benefits of carbon nanotubes themselves, but also the carbon nanotube coating alters the hydrodynamic boundary layer of the interface which enhances heat transfer coefficients (natural or forced convection) across the carbon nanotube-fluid interface (a fluid is defined as a gas or a liquid) and increases the net heat transfer surface area. These effects would also be noticed whether the fluid flow in the vicinity of the interface is laminar or turbulent. Moreover, due to the (e.g., high thermal conductivity and low electrical resistivity) can be utilized while at the same time facilitating the growth of nanotubes if certain other metal constituents are present and dispersed homogeneously in the alloy.

We have discovered that there are unexpected and multiple benefits by enhancing a metal substrate surface with carbon nanotubes. Heat transfer between two phases (e.g., between a gas or liquid (“fluid”) and a solid surface) depends on a series of “resistances” including natural or forced convention heat transfer, and conduction through a material (e.g., the carbon nanotube coating an underlying metal substrate). In order to enhance the net heat transfer rate, all of these resistances must be altered; otherwise the limiting “resistance” will dictate the net heat transfer rate. For example, if the conductivity of heat through a coating is very low, yet the heat transfer rate to this coating surface from the bulk fluid is high, the net heat transfer rate will still be low and limited by the conductivity through the coating. Therefore, we attribute the improvements to heat transfer that we have discovered by the methods of this invention to enhancement in all of these resistances. The scale of the nanotube structures on the surface are 10's-100's of nanometers. This nanoscale of surface roughness is not typically considered in the field of fluid mechanics and heat transfer, and therefore its benefits have not previously been appreciated.

The carbon nanotube coating surface is very porous and possesses a high surfaces area relative to the underlying metal substrate. Hence, the carbon nanotube coating will not only provide enhancement to the thermal conductivity resistance due to the intimate contact of the metal surface and the attached carbon nanotubes coupled with the known thermal conductivity benefits of carbon nanotubes themselves, but also the carbon nanotube coating alters the hydrodynamic boundary layer of the interface which enhances heat transfer coefficients (natural or forced convection) across the carbon nanotube-fluid interface (a fluid is defined as a gas or a liquid) and increases the net heat transfer surface area. These effects would also be noticed whether the fluid flow in the vicinity of the interface is laminar or turbulent. Moreover, due to the similarities of heat transfer and mass transfer, unexpected benefits to mass transfer would also be anticipated when using carbon nanotube coatings on substrates. Examples of mass transfer applications include, but are not limited to, the coating of catalysts used in oil refineries for the production of hydrocarbons and catalysts used in catalytic converters. The use of catalysts in refineries and catalytic converters in general involved the adsorption and subsequent desorption of gases or liquids at the surface of the catalysts where the gas or liquid compound reacts.

In heat transfer applications where liquids are evaporated or condensed, the carbon nanotubes will also introduce additional benefits with respect to nucleation or condensation sites. A higher concentration of nucleation sites will be present on a rough nanoscale coating of carbon nanotubes. This high concentration of small nucleation sites will benefit the formation of smaller vapor bubbles and the subsequent removal of vapor bubbles coalescing on the surface, which if too large, can blanket the surface and reduce the heat transfer rate (i.e., the heat transfer rate through a gas film is less than that through a liquid film) so maintaining a predominantly liquid film in the vicinity of a boiling surface has advantages over a surface covered by larger bubbles or gas films. We have discovered that a surface coated with carbon nanotubes in a boiling application creates a stream of very fine bubbles when compared side-by-side with a surface untreated with carbon nanotubes.

Many other heat transfer applications relate to flowing fluid through a channel or tube and exchanging heat between this fluid and the wall material, through the wall of the material comprising the channel, and then to another fluid or heat sink. Small dimension channels have been used with hydraulic diameter of less than 0.1 micrometer. Depending on the hydraulic diameter, these channels have been labeled from largest to smallest channels as conventional channels, minichannels, microchannels, transitional microchannels, transitional nanochannels, and molecular nanochannels. Channel walls may be linear, curvilinear, or a combination thereof. Channels are typically formed in materials with high thermal conductivity to minimize temperature gradients between the heat source or heat sink and the channel walls.

The heat transfer coefficient h is defined by q=h*A*(Twall−Tbulk) where q is the heat transferred, A is the surface area, and Twall−Tbulk is the temperature difference between the wall and the bulk fluid. Increasing either the surface area (A) or the heat transfer coefficient (h) will improve convective heat transfer. Nanotubes on small channel walls act as extended surfaces and can effectively increase both single-phase and two-phase heat transfer. Based on the aforementioned typical nanotube dimensions, nanotube/metal alloy composite walls will have a most significant effect on smaller channels since the percent increase in surface are per volume will be greater for a given coating as the diameter of the channel shrinks. However, one skilled in the art could also enhance surfaces of conventional channels with nanotubes in light of the teachings herein.

Another benefit of coating heat transfer surfaces is illustrated in a heat pipe device. A heat pipe is a means for transferring heat between two points, utilizing a fluid which evaporates and condenses at opposite ends, while being moved as a liquid from the condenser to the evaporator by capillary forces. The capillary forces result from fine grooves, screen, mesh, or the like, which are incorporated into the heat pipe. We discovered a surprisingly large increase in heat flux capacity of a heat pipe coated with carbon nanotubes relative to an equivalent uncoated heat pipe. Although some increase might be expected due to some surface area increase, the 200-300% increase in flux we measured was not expected. We attribute this unexpected benefit to many effects related to the carbon nanotube coating. One effect is an unexpectedly large increase in liquid pumping ability of the pipe resulting from the added microstructure and porosity of the carbon nanotubes in the heat pipe grooves. Another benefit is the unexpectedly large additional surface area of the grooves as a result of coating with the porous carbon nanotubes which enhances heat transfer. A further unexpected benefit may result from the nanotube network itself present on the surface of the grooves which can also act as an additional pump to move fluid from the condenser end to the evaporator end. Lastly, as discussed above, heat transfer rates and mass transfer rates can be surprisingly enhanced by the nanotube surface by altering the hydrodynamic boundary layer as vapor and liquid flow across the undulating surface.

In general, we have found that the unexpected enhancements to heat transfer will be optimized when using a coating substrate which contains metals with a high thermal conductivity. This reduces the thermal conductivity resistances and provides for the observance of the unexpected enhancements attributed to the carbon nanotube coating, and many of these metals also form solid solutions carbon which facilitates the growth of carbon nanotubes directly on the surface of the metal substrate. Examples of high thermal conductivity metals include silver (Ag), copper (Cu), aluminum (Al), gold (Au), zinc (Zn), rhodium (Rh), iridium (Ir), beryllium (Be), nickel (Ni), chromium (Cr), tungsten (W), cobalt (Co), molybdenum (Mo), calcium (Ca), ruthenium (Ru), cadmium (Cd), and brasses, and alloys thereof. All these metals have thermal conductivities greater than about 90 W/m-K. For reference, the value for iron (Fe) is 80 W/m-K.

In general, we have found that the unexpected enhancements to electrical energy storage or retrieval will be optimized when using a coating substrate which contains metals with a low electrical resistivity. This reduces the electrical resistances and provides for the observance of the unexpected enhancements attributed to the carbon nanotube coating, and many of these metals also form solid solutions carbon which facilitates the growth of carbon nanotubes directly on the surface of the metal substrate. Examples of low electrical resistivity metals include silver (Ag), copper (Cu), aluminum (Al), gold (Au), zinc (Zn), rhodium (Rh), iridium (Ir), beryllium (Be), nickel (Ni), tungsten (W), cobalt (Co), molybdenum (Mo), calcium (Ca), ruthenium (Ru), cadmium (Cd), magnesium (Mg), potassium (K), osmium (Os), and indium (In), and alloys thereof. All these metals have electrical resistivities less than about 9 micro ohms-cm. For reference, the value for iron (Fe) is 10.1.

We have also discovered surprising benefits to use carbon nanotube coated metal substrates for electronics applications such as batteries (e.g., Li ion) and ultracapacitors. Current state-of-the-art lithium batteries use transition metal oxides (i.e., LixCoO2 or LixMn2O4) as the cathodes and carbon materials (graphite or disordered carbons) as the anodes. Often, carbon films (not nanotubes) are simply deposited on copper or aluminum sheets, or sometimes the carbon is formed into hard pellets. The specific energy capacity for lithium ion batteries in milliamp-hours per gram of carbon, or mAhr/g, is determined by the saturation lithium concentration of the electrode materials. For graphite, the thermodynamic equilibrium saturation concentration is six carbon atoms to one lithium atom (a stoichiometry of LiC6), which is equivalent to 372 mAhr/g. It has been speculated that higher capacities would be possible if all the interstitial sites are accessible for Li intercalation, such as is the case for carbon nanotubes. This implies that the saturation concentration of the carbon would be dictated by a stoichiometric of LiCx, where x is less than 6.

Lithium ion batteries function by a “rocking-chair” movement of Li ions between two electrodes, one of which usually comprises carbon in some form. Atoms of an electron-donating compound undergo an oxidation reaction to form ions of the donating compound plus free electrons. The ions are then absorbed by the opposite electrode, and the free electrons travel through the electrical circuit. The carbon electrode adsorbs the Li ions and stores them until the current is reversed (i.e., recharging). The current in a circuit is then a measure of the number of ions which are adsorbed or transferred to the carbon electrode. The specific energy capacity of the battery is thus reflective of the number of ions (e.g., Li) which can be adsorbed or held by the opposing electrode.

Lithium ion batteries are typically comprised of a cathode, anode, separator membrane, and electrolyte. The cathode provides the Li to the battery cell, which moves between the cathode and anode during charging and discharging. Materials comprising cathodes in state of the art Li ion batteries include, but are not limited to lithium, compounds such as LiCoO₂, LiMn204, and LiNiO₂, as well as graphite, carbon, lithium carbonate, and a polymeric binder. The quantity of Li applied to the cathode determines the ultimate capacity of the Li ion battery. One of the currently preferred polymers used as a binder is poly(vinylidene fluoride), or pVDF, but other polymers can be used including, but not limited to, thermoplastic and co-polymers. A binder is generally used to physically hold the electrode together, and can also serve as an “adhesive” when the cathode, anode, and separator are assembled.

The materials comprising the cathode can be mixed and applied in a solvent (e.g., acetone, N-methyl-2-pyrrolidone (NMP), and tetrahydrofuran (THF)) slurry onto a metal current collector including, but not limited to, aluminum or copper, followed by evaporation of the solvent. One or both sides of the collector material can be coated with the cathode formulation. These electrodes can also be subsequently pressed, compression molded or laminated with or without heat after applying and drying this coating. Other lithium ion batteries have used lithium metal as the cathode. Those skilled in the art will understand the various known ways in which to formulate and form these cathode electrodes.

Electrolytes common to current lithium ion batteries include, but are not limited to, LiPF₆, LiClO₄, and LiBOB (BOB is the anion with the boron coordinated by oxalate groups). These electrolytes are dissolved in various proportions into a solvent, typically between about 0.5 and 3 moles per liter. Solvents currently preferred in the art include, but are not limited to, ethylene carbonate, diethyl carbonate, propylene carbonate, dimethyl carbonate, and methyl ethyl carbonate. The separator membrane between the cathode and anode allows for the migration of Li ions between the cathode and anode. Currently preferred membranes are polymeric, but any other membrane can be used provided it functions to allow migration of Li ions back and forth between the electrodes. One currently preferred microporous membrane is a polypropylene-polyethylene composite, but other materials have been used in the art, including but not limited to, polypropylene, polyethylene, and other polyolefins.

The anode electrode of lithium ion batteries contains carbon which intercalates the Li ions resulting from the cathode during charging. Often, carbon films (not nanotubes) are simply deposited on copper or aluminum sheets, or sometimes the carbon is formed into hard pellets. U.S. Pat. Nos. 5,705,292; 6,475,679; 6,682,863; 6,764,767; 6,692,874; 6,803,149; 6,818,352; 6,692,543; 6,132,477; 5,552,239; and 6,024,773), for example, describe typical compositions and the ways to prepare these electrodes with carbon, whereby the carbon, a polymer binder, and optionally other additives are slurried and applied to a collector plate, typically copper, dried, and optionally laminated compression molded, or pressed. One or both sides of a collector material can be coated with this anode formulation. Various types of “loose” carbon have been described in the aforementioned patents.

In this invention, the carbon, in the form of carbon nanotubes, is first grown directly onto a collector plate or foil. The preferred collector plates of this invention are copper alloys, although other metals and metal alloys can be used that are suitable for direct growth of carbon nanotubes. Next, a binder solution containing a polymer such as pVDF is dissolved in a solvent, and optionally applied to the collector plate with the carbon nanotubes, and the solvent is evaporated. The resulting electrode contains a coating of carbon nanotubes with precipitated polymer that can be pressed or laminated, with or without heat, to flatten and further immobilize the carbon nanotubes attached to the electrode. The binder is used for additional strength to the carbon nanotubes that are attached to the collector plate.

One advantage of this invention is that the polymeric binder is optional, since the carbon nanotubes are already attached to the electrode surface by the chemical vapor deposition process, in contrast to the prior art which requires this binder since the carbon is added to the collector plate as loose particles in a slurry. The carbon nanotubes are also integrated firstly with, and attached by chemical forces to, the collector polate which improves electrical contact with the collector plate and reduces internal battery resistances. Prior approaches relied on physical contact between the “loose” carbon coating and the collector plate.

The entire lithium ion battery assembly comprised of at least one cathode, at least one anode, and at least one separator can be further pressed, compression molded, or laminated to provide an integrated body. More than one anode, more than one cathode, and more than one separator can be stacked to form a lithium ion battery, and the final assembly may be used as a flat sheet or rolled into a cylinder. The membrane can be used as a separate sheet placed between the electrodes, or, one of the electrodes could be placed inside a bag or sleeve comprised of the membrane material. The final assembly is then placed in a container and contacted with the electrolyte solution.

Other researchers have shown irreversible capacities of 1800 mAhr/g, and reversible capacities of 1000 niAhr/g using solution-deposited carbon nanotubes (e.g., see U.S. Pat. No. 6,422,450), but this data may have been collected using faulty methodology. Specifically, the cells were cycled between 3.1V and ˜0.0V, which is not the proper operational regime of a Li-ion battery. In fact, it implies that the charging and discharging in these cases results from the chemical breakdown of the electrodes rather than from Li-ion intercalation and de-intercalation. Prior Examples 11 and 12 in our application Ser. No. 10/831,157 were experiments undertaken prior to our recognition of the faulty prior art test methods which we had paralleled. We have since recognized that the correct operating voltage for Li ion batteries is between about 2.5 volts and about 4.3 volts, although those skilled in the art will also recognize that different electrode materials as well as electrolytes may allow for a somewhat wider range of voltages without detrimental effects to battery cell stability.

With corrected basic test methods, we conducted discharge tests on several battery electrodes made with CNTs (see new Example 11 below). In general, the discharge capacity of the cells can be determined using a Potentiostat/Galvanostat apparatus. There are numerous methods of charging the cells, but the discharge is normally conducted at constant amperage. The capacities are then usually normalized according to the active weight of the anode material. Using electrodes manufactured by the methods of the present invention, the measured capacities were twice as high as capacities of electrodes made with conventional activated carbon. The data is reported compared to activated carbon due to the non-optimization of bench-top apparatus used by us, but all non-optimized factors were kept constant throughout the tests with only the form of the carbon on the anode changing. Therefore, the improvement in capacity is thought to be due entirely to the CNTs. Furthermore, we now believe that the unexpected energy storage benefits taught by this invention are due at least in part to the method of carbon nanotube deposition on the metal substrates.

In the prior art, carbon nanotube coated electrodes were produced by a solution-deposition method. These carbon nanotube electrodes were formed by first suspending powderized nanotubes in a suitable solvent via sonication, and then a suitable electrode substrate material, such as copper, was lowered into the mixture or the carbon nanotube suspension was applied to the substrate surface. Finally, the solvent was evaporated off, leaving a fine coating of nanotubes suspended on the substrate. These nanotube coated electrodes were then inserted into the battery. One method used in prior art to grow the nanotubes for these coatings was by way of a support material (e.g., alumina or silica) containing a catalyst. This approach required that the nanotubes and support material were first digested in acid at a temperature above ambient as a means of separating the carbon nanotubes from the support material (e.g., alumina, silica) and catalysts prior to suspending the carbon nanotubes in the solution to coat the electrodes. This process dissolved the support material and catalysts leaving mostly carbon nanotubes. Ultrasonication was also sometimes used in this process.

Carbon nanotubes produced by similar means in the prior art were also sometimes purified by suspension in media such as alcohols with ultrasonication. This approach is problematic, in that during the acid digestion and/or ultrasonication process to remove the support material and catalysts, the carbon nanotubes could be damaged or altered which can affect their physical and chemical properties. The present invention also teaches surprising benefits because much prior art has come to the conclusion that damage to the nanotube structure, such as through ball-milling, increases the energy density of carbon nanotube electrodes by providing additional sites for lithium intercalation. The different studies are inconclusive as to how long samples should be ball-milled with durations ranging from a few minutes to several hours. While the data for the prior art may indeed be valid for the specific circumstances of those studies, our process has proven that much superior capacities can be attained by not destroying the structure at all. The prior studies all used nanotubes that had been through the substrate separation processes, during which impurities or residue from the acid or alcohol are adsorbed onto the carbon surface essentially poisoning once active sites which makes them unavailable for Li intercalation. It is equally likely that the ball-milling or sonication processes employed in prior art increased capacity by simply separated the nanotubes from these impurities as opposed to adding additional intercalation sites. Lastly, these processes for coating electrodes with solution deposited carbon nanotubes was also costly and time intensive due to the multiple process steps and more raw materials required.

Inorganic compounds which can be formed into nanotubes or fullerene type structures include, but are not limited to MoS2, SiO2, Al2O3, ZrO2, BN, WS2, V2O5 as described by Tenne and Zettl (“Nanotubes from Inorganic Materials,” M. S. Dresselhaus, G. Dresselhaus, Ph. Avouris (Eds): Carbon Nanotubes, Topics Appl. Phys. 80, 81-112 (2001), ©Springer-Verlag Berlin Heidelberg 2001). The growth of these inorganic nanotubes directly onto the surfaces of metals will provide for controlled layers of various wear resistance or self lubricating materials to both internal and external metal surfaces. These inorganic compounds could also be combined with carbon nanotubes on a metal substrate to produce a composite inorganic-carbon nanotube coated substrate.

Another unexpected discovery of this invention is that the carbon nanotubes deposited by the methods of this invention do not need to be 100% pure on the surface of the metal substrate to achieve the surprising benefits in specific energy capacity. The deposited carbon coating on the metal substrate will contain varying quantities of SWNT's, MWNT's, “bucky onions,” and other ordered carbon structures, as well as amorphous carbon, depending on the specific CVD production parameters (e.g., gases, temperatures, and times) used. The prior art has focused intensely on purifying the carbon nanotubes before solution-depositing onto a substrate. Since we have found that this purification step is unnecessary, our invention provides additional benefits to producing carbon nanotube coated electrodes in a single-step process which is faster and less costly than those methods taught in the prior art.

Solution-deposited carbon nanotubes will also be difficult to align perpendicularly to a surface since these nanotubes were not grown from, or attached to, the metal substrate. Directly growing the nanotubes onto a battery electrode provides benefits with respect to electron flow and internal resistance since there is no discontinuity between the carbon nanotube and the metal substrate. Directly attached carbon nanotubes will also provide a benefit of extended life because the coating will be less easily worn off compared to carbon nanotubes which are solution deposited. This unexpected benefit also has utility in the field of sensors which preferably now will not be comprised of nanotubes that will wear off or degrade with time.

A related application is an ultracapacitor where we expect surprising benefits to using the methods of our invention to produce the electrodes in these devices. As with conventional capacitors, an ultracapacitor has two conducting surfaces to generate an electric field across a dielectric where energy is stored. The double layer is created at a solid electrode solution interface; essentially, a charge separation occurs at the interface between the solid and the electrolyte. In most ultracapacitors, the electrode is carbon combined with an electrolyte. For an ultracapacitor electrode to store the maximum charge possible, it must have a maximum proportion of active mass and an optimum accessibility to this mass. The latter property requires that it should have an open porous structure. Much work has been performed on ultracapacitor technology to increase the surface area of the carbon electrode. Carbon nanotubes possess very high surface areas and porosity and would provide benefits to ultracapacitor performance.

Prior methods of producing the ultracapacitor electrodes rely on forming suspensions or mixing carbonaceous material with a polymer binder which is then extruded, used as a coating, or otherwise spread to form the electrodes. These processes are not generally cost effective and require multiple process steps, and they are not amenable to spooling.

We anticipate that employing nanotubes in these state-of-the-art processes would result in, the suspension, mixing or binding processes damaging the carbon nanotubes or poisoning of active sites on the nanotubes, thereby reducing their capacity. Moreover, we expect surprising increases in energy storage densities with the process of invention since the carbon nanotubes are coated in situ on substrates with no need to further purify or subject the nanotubes to harsh conditions (e.g., acids, high temperatures, solvents, sonication, milling). Similarly to battery electrodes, there will also be unexpected benefits to using less than 100% purities of nanotubes. Other advantages of our invention are in the single step process of coating and the ability to adapt the process to spooling. An additional benefit is that, by depositing directly on the current collector, overall capacitor construction is simplified. Directly growing the nanotubes onto an electrode provides benefits with respect to electron flow since these is no discontinuity between the carbon nanotube and the metal substrate. Directly attached carbon nanotubes will also provide a benefit of extended life since the coating will be less easily worn off compared to carbon nanotubes which are spread onto a surface.

We have also discovered that metal alloys can be deposited by e-beam or sputtering onto substrates to form patterns useful in electronics devices (e.g., chemical sensors, electrodes, circuit boards). In one preferred method, a silicon oxide support substrate is masked with photoresist and then coated with the metal alloys by e-beam deposition, followed by dissolution of the photoresist mask. The metal alloys could also be deposited using a shadow mask, photomask, or an entire substrate could be coated with the metal alloys by e-beam or sputtering and then chemically etched off to form patterns. The patterned metal alloys are then coated with carbon nanotubes as taught by the present invention. Fine patterns of carbon nanotubes having pattern dimensions of about 1 micron or less can be produced by this method. This method can also produce perpendicularly aligned nanotubes which have benefits in electronic devices. Further, these nanotubes can be treated with plasma to remove amorphous carbon and/or sharpen the tips of the SWNT's or MWNT's attached to the patterned alloy surface. Preferred gases used for plasma etching include carbon tetrafluoride, oxygen, ammonia, and water. This method provides a limitless way of producing circuitry patterns with directly grown and attached carbon nanotubes without separate steps for solution depositing the carbon nanotubes. This method also has advantages to solution deposition in that contiguous patterns of alloy catalysts will be formed rather than a mixture, or amalgam of metals. Furthermore, this invention provides improvements to solution deposition: Solution deposition would not allow for alloy deposition since individual metal components of the alloy would dissolve in solution and would then precipitate separately on a substrate and not as an alloy. Other support substrates such as porous silicon oxide, alumina or zeolites could also be used to deposit the patterned metal alloys coated with carbon nanotubes by, this method. In one currently preferred embodiment, the patterned metal alloy-carbon nanotube composite is then assembled into a chemical sensor whereby the patterned substrate serves as an electrode.

We have also discovered that the coatings produced by the methods of this invention can be difficult to remove mechanically (e.g., by scribing), thereby indicating a strong adhesion to the metal substrate. In fact, it is likely that the coatings produced using the present invention are held to the metal substrates by chemical bonds or atomic forces. This property also provides a way to coat lubricating surfaces of metals and alloys for applications such as bearings and implantable medical devices or prostheses. SEM analysis of the coating coupons also reveal that the nanotubes are growing from and attached to the substrate surface. These coatings are also difficult to remove chemically. For example, coated alloys have been subjected to a nitric acid soak for 45 minutes with no effect on the carbon nanotube coating.

In addition, we have discovered that by varying the feedstock flow rates and furnace temperatures, we can grow a thicker layer of carbon and carbon nanotubes on the metals substrates. This provides a way to grow nanotubes for other applications such as polymer composites by scraping off the grown nanotubes for use in other applications.

Preferred metal alloys will contain metals that are known by those skilled in the art to facilitate or promote the growth of nanotubes. For carbon nanotubes, it is typical that these metal constituents have the ability form solutions with carbon. A few of the alloys which we have found to fulfill this requirement are CDA 704 (91% Cu, ˜1.5% Fe, ˜5.5% Ni), CDA 706 (88% Cu, ˜1.5% Fe, ˜10% Ni), Hastelloy G-30 (43% Ni, ˜30% Cr, ˜15% Fe, ˜5% Mo), Incoloy MA956 (74% Fe, 5% Al, 20% Cr, 0.5% Y203), and Hastelloy C-276 (57% Ni, ˜16% Cr, ˜6% Fe, 16% Mo).

Other metal substrates which can be used in this invention include tradenames Allvac®, Nickelvac, Carpenter, Elgiloy®, Haynes®, Stellite®, Stoody®, Tribaloy®, Hastelloy®, INCONEL®, NIMONIC®, NILOT®, Allegheny Ludlum, Monel™, INCO™, Deloro®, Osprey Metals, INCOLOY®, Nichrome™, and Super Alloys, as well as other alloys based on stainless steel, carbon steel, copper (UNS series 100, 600, 700, 800 and 900), nickel, brass, and titanium. These preferred alloys are generally comprised of combinations of 2 or more elements in the following weight percentage ranges: Cu from 0% to about 95%, Fe from 0% to about 76%, Ni from 0% to about 78%, Mo from 0% to about 85%, Y2O3 from 0% to about 1%, Mn from 0% to about 15%, Zn from 0% to about 39%, Cr from 0% to about 52%, Co from 0% to about 63%, Pb from 0% to about 15%, Sn from 0% to about 13%, Al from 0% to about 12%, Si from 0% to about 4%, W from 0% to about 16%, Ti from 0% to about 98%, Ag from 0% to about 50%, Zr from 0% to about 10%, and other minor constituents.

The thickness of the nanotube layer produced by this invention are typically 1 micrometer or thicker, depending on the CVD furnace conditions and carbon feedstock vapors used. Thinner coatings less than 1 micrometer could also be produced by adjusting the CVD soak time, temperature, and feedstock. The nanotube diameters can range from a few nanometers to several hundred nanometers. The individual catalytic metal islands or grain sizes in the preferred metal alloys are typically 1 to 10 nanometers by 1 to 10 nanometers. Larger islands could also facilitate carbon nanotube growth. The size of the metal catalyst islands will affect the size of the nanotubes, e.g., multi-walled versus single walled nanotubes. Those skilled in the art will understand that this invention can be applied to the growth of SWNT's or MWNT's on metal substrates, and the relative proportion of these types of nanotubes can be varied by the type of alloy and grain sizes, as well as pretreatment to the alloys which can anneal and increase the grain and metal island sizes on the surface of the alloy.

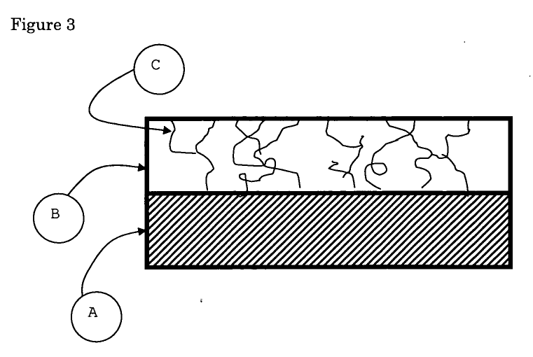

We have also discovered that this invention can be applied to the production of metal-carbon nanotube-polymer composites. The coated metal substrate can be dipped, sprayed or otherwise coated with a thermoset or thermoplastic polymers to immobilize and encapsulate the carbon nanotubes attached to the surface of the metal substrate. After formation and setting of the polymer coating, the polymer may optionally be machined to expose the tips of the carbon nanotubes. The method used to expose the nanotubes embedded in the polymer coating can be mechanical (e.g., sanding or milling) or chemical (e.g., plasma etching, acid etching). These composites can then be used for applications including, but not limited to, electronics devices such as sensors, FET's, batteries, ultracapacitors, fuel cells, as well as heat transfer devices such as heat exchangers, heat pipes, and heat sinks. The advantages to using these metal alloy-nanotube composites in this form include hydrophobicity or hydrophilicity, (depending on the application and type of polymer used) increased durability to wear and erosion, and increased strength of the laminate. FIG. 3 depicts the structure on these composites and laminates. The metal substrate A is coated with nanotubes C, and then further coated with a polymer B.

The carbon nanotubes coating can also be used advantageously on metals and metal alloys to prevent or limit corrosion. The method of this invention can thus be used to coat metal substrates used in environments which are prone to corrosion. We also contemplate that other nanotube materials could be used advantageously in corrosive environments.

Hydrogen storage is another application which typically uses metal alloys. Many of the metal constituents of these alloys can facilitate or promote the growth of carbon nanotubes. Carbon nanotubes have been shown to be effective hydrogen storage media, and composites of metal alloys and carbon nanotubes will also provide hydrogen storage benefits of capacity and weight, and hydrogen absorption/desorption kinetics, hydrogen dissociation kinetics. The carbon nanotube coating will also protect the underlying metal alloy from poisoning which can be problematic for hydrogen storage and related applications such as catalytic reformers and electrodes in fuel cells. The metal alloys can be used is a powder or granule form and coated with carbon nanotubes using the methods of this invention. The powders of the metal alloys can range in size down to 100's or even 10's of nanometers. Metal hydride alloys which can be coated with carbon nanotubes include, but are not limited to, ZrNi_{0.95}M_{0.05}, TiFe_{0.9}Mn_{0.1}, Mg₂Ni, and CaNi₅. Others potentially useful compounds are TiFe, TiFe_{0.9}Mn_{0.1}, CaNi₅, Ca_{0.7}M_{0.3}Ni₅, LaNi₅, Mg₂Ni, Mg₂Cu, Mg₂Al₃, Zr(Ni_{0.95}M_{0.05}), Ti(Fe_{0.8}Ni_{0.2}), ZrFe_{1.5}Cr_{0.5}, LaNi_{4.7}Al_{0.3}, and LiAl, where M is a mischmetal (a combination of various rare earth metals). These metal alloys can be categorized as type AB₅, A₂B, and AB. The composition of metal alloys used for hydrogen can vary widely and can include one or transition metal, optionally in combination with one or more rare earth metals and/or one or more alkaline metals.

### EXAMPLE 1

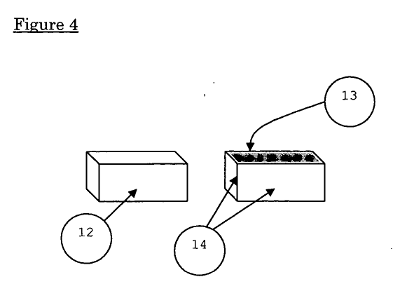

The alloys CDA 704 (91% Cu, ˜1.5% Fe, ˜5.5% Ni), CDA 706 (88% Cu, ˜1.5% Fe, ˜10% Ni), Hastelloy G-30 (43% Ni, ˜30% Cr, ˜15% Fe, ˜5% Mo), Incoloy MA956 (74% Fe, 5% Al, 20% Cr, 0.5% Y2O3), and Hastelloy C-276 (57% Ni, ˜16% Cr, ˜6% Fe, 16% Mo) were pickled using methods adapted from ASTM method G1-03. The metals were then introduced into a CVD furnace. The material was heated to and held at 900 C for 2.5 hrs while flowing combinations of ethylene (20 sccm), methane (1000 sccm), and hydrogen (500 sccm) gases over the substrates. FIG. 4 depicts the metals alloy substrate 12 before and after carbon nanotube coating. The carbon nanotubes grow on the upper face 13 and also on the edges 14. The bottom surface of the coupon will also be coated to some degree.

### EXAMPLE 2

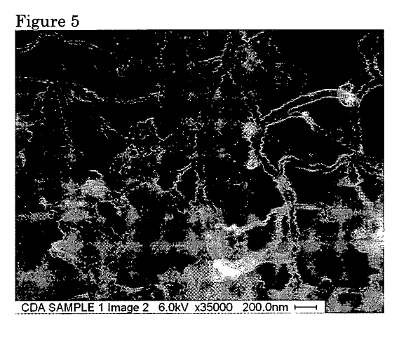

The alloy CDA 704 (91% Cu, ˜1.5% Fe, ˜5.5% Ni) was pickled using methods adapted from ASTM method G1-03. The material was heated to and held at 900 C for 2.5 hrs while flowing combinations of ethylene (20 sccm), methane (1000 sccm), and hydrogen (500 sccm) gases over the substrate. The surface was then analyzed using SEM. FIG. 5 is a 35000×SEM image of nanotubes produced during the process. Some nanotubes are longer than 2 micrometers in length, with diameters of about 10 to 100 nm.

### EXAMPLE 3

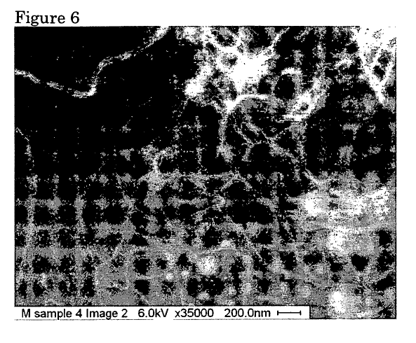

An Incoloy MA 956 alloy (74% Fe, 5% Al, 20% Cr, and 0.5% Y2O3) was pickled using methods adapted from ASTM method G1-03. The material was heated to and held at 900 C for 2.5 hrs while flowing combinations of ethylene (20 sccm), methane (1000 sccm), and hydrogen (500 sccm) gases over the substrate. The surface was then analyzed using SEM. FIG. 6 is a 35000×SEM image of nanotubes produced during the process. Some nanotubes are longer than 2 micrometers in length, with diameters of about 10 to 50 nm.

### EXAMPLE 4

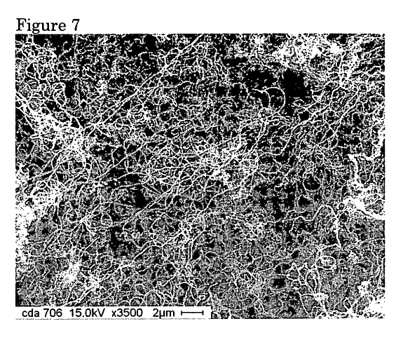

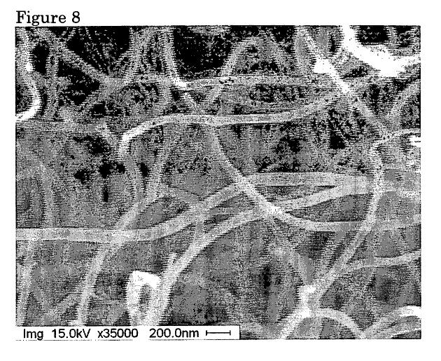

The alloy CDA 706 was pickled using methods adapted from ASTM method G1-03. The metal was then introduced into a CVD furnace. The material was heated to 1000 C for 30 min hrs using combinations of ethylene (5 sccm), methane (500 sccm), and hydrogen (500 sccm) gases. The surface was then analyzed using SEM. FIGS. 7 and 8 are SEM images of nanotubes produced during the process. The nanotubes are very uniform with most diameters of about 50 nm and some lengths exceeding 20 micrometers.

### EXAMPLE 5

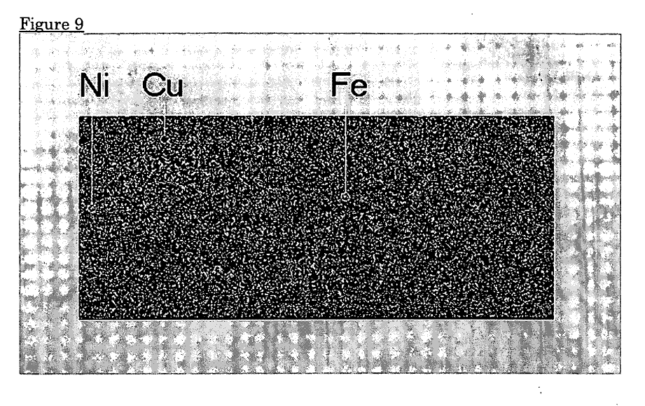

The alloy CDA 706 was analyzed by an X-ray energy dispersive spectrophotometer to measure the grain size of the alloy constituents on the surface of the substrates. FIG. 9 is the image from the scan. The grain size of the nickel, iron, and copper was typically 4 nm×4 nm or less. The metal constituent grain or island size directly affects the diameters of nanotubes grown from the substrate at metal constituent islands or grains.

### EXAMPLE 6

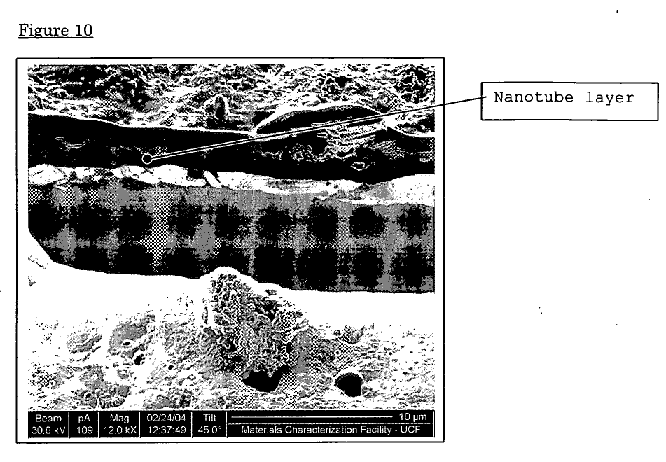

The coating thickness was measured on a CDA-704 alloy coated with carbon nanotubes. FIG. 10 is the SEM photograph of a sample which had been ion milled and platinum coated, in which the carbon nanotube coating thickness is approximately 2 microns.

### EXAMPLE 7

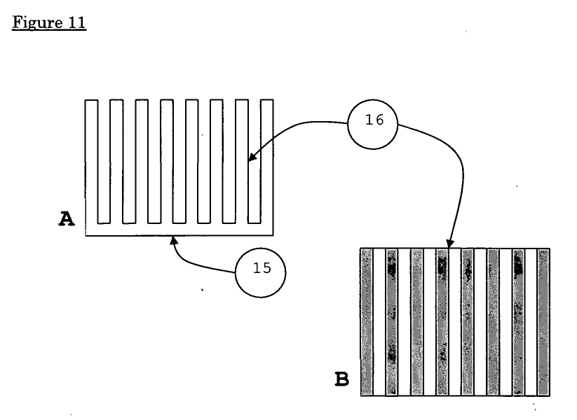

A heat sink comprised of copper alloy CDA 706 was coated in accordance with present invention. FIG. 11 schematically shows the carbon nanotube coated heat sink 15 with fins 16 comprised of metal alloys. The left half A is a side view and the right half B is a top view of the coated heat sink.

### EXAMPLE 8

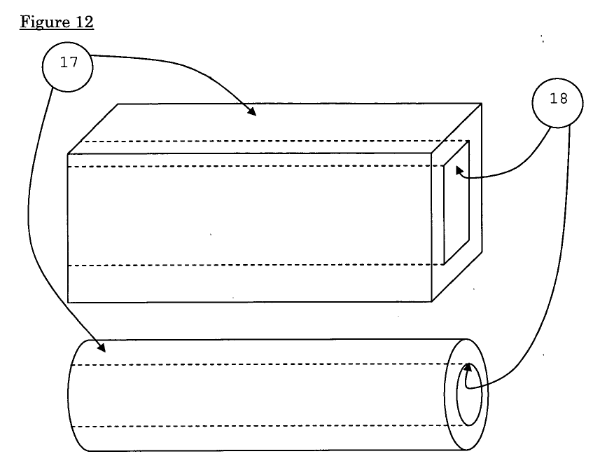

An axial groove heat pipe comprised of copper alloy CDA 706 was fabricated and coated using the methods of this invention. FIG. 12 shows that a square heat pipe and a cylindrical heat pipe 17 with an inner grooved surface 18 which is coated with carbon nanotubes. Other geometries of heat pipes and various groove configurations can also be coated using the present invention. Heat pipe wicking material such as screens in addition can be coated with carbon nanotubes and inserted into heat pipes.

### EXAMPLE 9

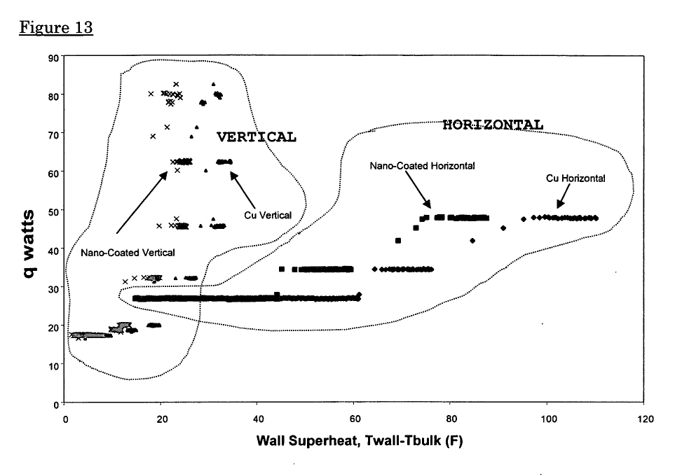

Nanotubes were grown on copper alloy CDA 704 (91% Cu, ˜1.5% Fe, ˜5.5% Ni). Heat flux versus the temperature difference between the wall and bulk water were analyzed for a one inch square nanotube-coated and un-coated copper sample in vertical and horizontal configurations. Heat transfer curves for vertical and horizontal orientations are shown in FIG. 13. For each orientation, the graph depicts “Nano-coated” and “Cu” data points. The Nano-coated data is for carbon nanotube coated Cu alloy, and the “Cu” data points are uncoated Cu alloy. The heat transfer coefficient h is defined by q=h*A*(Twall−Tbulk) where q is the heat applied, A is the surface area, and Twall−Tbulk is the temperature difference between the wall and the bulk fluid. The heat flux is q/A, and A was kept constant in our experiments. FIG. 13 shows that for a given heat flux q/A (or equivalently, q), the nanotube coated surface always exhibits a lower wall superheat (Twall−Tbulk) in both vertical and horizontal orientation. Since q=h*A*(Twall−Tbulk), h=q/A/(Twall−Tbulk) and a lower Twall−Tbulk translates to a higher heat transfer coefficient h. This improved performance was supported by visual examination of the test. For example, for the subcooled pool boiling experiments, on the horizontal plates, very small bubbles could be seen steadily exiting the nanotube coated surface and no bubbles were visible on the uncoated copper surface. At 20° F. temperature gradient, the benefit in improved heat transfer is 60%, and at 30° F., the improvement in heat transfer is 37%. The benefit for horizontal surfaces is were even greater. For the horizontal configuration (heated surface facing upward), the wall temperatures are 19° F. lower on the nanotube coated surfaces. Due to the nanotube fabrication process disclosed herein, the nanotube extended surface is chemically bonded to the base metal and the conductivity of the nanotubes is extremely high, making the nanotubes an excellent extended surface, and ideal nucleation zone.

### EXAMPLE 10

Two identical axial groove copper water heat pipes similar to FIG. 12 were fabricated from copper (CDA-706) and then a nanotube coating was grown on the axial grooves of one of the heat pipes before assembly. The nanotube coated heat pipe was first pickled and then coated with carbon nanotubes in a CVD furnace using methane and ethylene feedstock gases. The heat pipes were made from four 1.25″×1.25″×7″ (long)×0.25″ (thick) copper plates that were welded, along with end caps, to form a rectangular heat pipe of dimensions 1.25″×1.25″×7″ long. For the nanotube coated heat pipe, the four individual sides of the heat pipe were nanotube coated, prior to welding into a heat pipe assembly. The surfaces can also be coated after assembly. To determine the effect of welding the heat pipe together after nanotube coating, and to determine if the nanotube coating would affect the welding process, a small test piece was fabricated before the actual heat pipes were fabricated. The copper sections could be successfully welded after being coated with nanotubes and no special surface cleaning was required prior to welding.

The axial grooves on these heat pipes were 0.012″ deep, with a width of 0.006″ and the grooves were located with a center-to-center distance of 0.035″. After fabrication, the heat pipes were charged with water. The uncoated copper-water heat pipe was charged with 2.52 grams of water and the nanotube-coated copper-water heat pipe was charged with 2.32 grams of water.

The two essentially identical heat pipes were tested in parallel in a horizontal test stand. Each heat pipe was fitted with four heaters around the last inch of the heat pipe's evaporator section. The last inch of the condenser section of each heat pipe was clamped to an isothermal block of aluminum, with a heat flux sensor sandwiched between the heat pipes and the aluminum block. This aluminum block was cooled with an ice bath and remained at 2.2° C. (36° F.) for the duration of all the tests. Six thermocouples were attached to each heat pipe along the center line of one side of the heat pipe. The first thermocouple (labeled as location a) was located 1.5″ from the end of the evaporator section (note the heaters were located in the first inch of the evaporator section, one on each side for a total of 4 heaters), the next thermocouple, labeled location b, was located 2.5″ from the end of the evaporator section, the third thermocouple, called location c, was located 3.5″ from the end of the evaporator section, the fourth thermocouple, called location d, was located 4.5″ from the end of the evaporator section, the fifth thermocouple, called location e, was located 5.5″ from the end of the evaporator section, the sixth (and last) thermocouple, called location f, was located 6.5″ from the end of the evaporator section (or 0.5″ from the end of the condenser section).

The performance comparisons were performed over a range of heat powers (up to the maximum power of the test stand). The heat pipe remained nearly isothermal for the nanotube coated heat pipe, as was expected for a properly operating heat pipe. For one test, we found the maximum temperature difference to be 5° C. at lower inputted powers and to decrease to 1.4 as the heat flux increased to the maximum capacity of the test stand, namely 2700 W/m2. For the identical uncoated heat pipe, the temperature gradient between locations a and f severe, indicating that the heat pipe was not operating normally, and that the imposed heat flux was beyond the capacity of the heat pipe for all but the lowest heat fluxes tested. In the identical test as with the nanotube coated heat pipe, the temperature difference was 7° C. at low power (540 W/m2) and increased to 51° C. as the heat flux was increased to the maximum of 1875 W/m2.

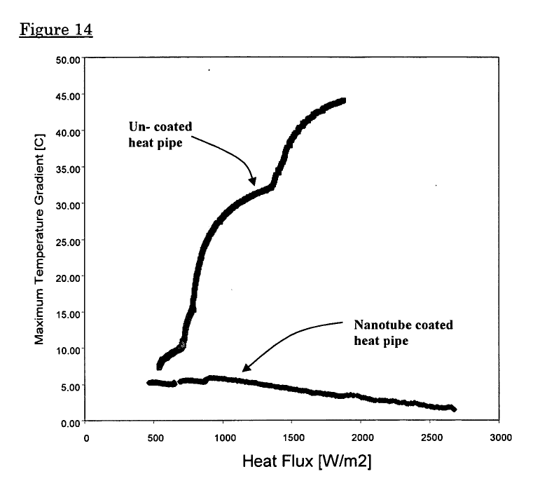

FIG. 14 shows a comparison of the maximum heat pipe temperature gradient which is the temperature difference between location a (the evaporator end and the warmest location) and location f (the condenser end and the coolest location), for both the nanotube coated and uncoated axial groove copper alloy-water heat pipes. The figure clearly shows that the uncoated copper heat pipe performance degrades quickly (above about 700 W/m2, as exhibited by the unacceptable temperature gradient along the length of the untreated heat pipe), as the power is increased, whereas the nanotube coated heat pipe maintains a low temperature gradient over an even wider heat flux range.

Referring to FIG. 14, it can be seen that the uncoated heat pipe has a maximum heat flux capacity of about 700 W/m2; however, the carbon nanotube coated heat pipe displays excellent heat flux capability all the way up to the maximum heat flux tested (maximum capacity of the test stand). Actually, based on the steady decrease in the thermal gradient as the heat flux is increased, it is certainly reasonable to expect that the maximum heat flux for the nanotube coated heat pipe may be significantly higher than the 2700 W/m2 achieved to date. Merely assuming, however that the currently measure value of 2700 W/m2 is the maximum capacity of the carbon nanotube coated heat pipe, still results in an 285% improvement in the heat flux capability of a copper water heat pipe solely by the addition of carbon nanotubes onto the surface of the axial grooves.

### EXAMPLE 11

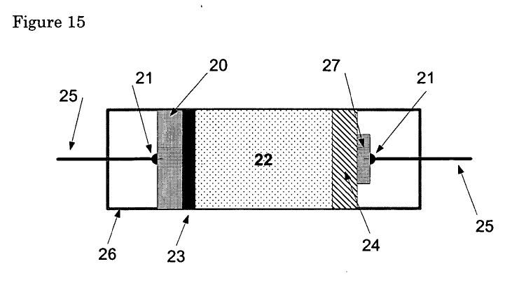

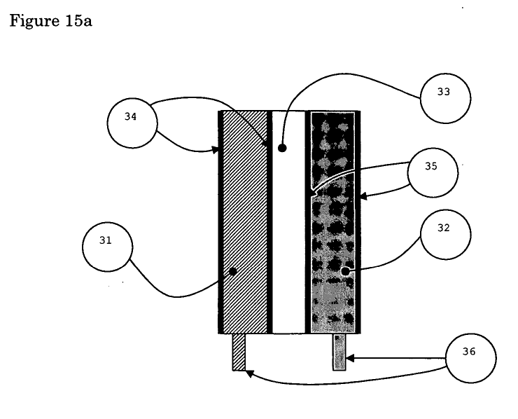

A lithium ion battery assembly comprised of one cathode, one anode, and at one separator was formed into a battery. The electrolyte used for this battery was a 1 mole per liter solution of LiClO4 in a 50/50 mixture of ethylene carbonate and dimethyl carbonate. The anode and cathode were approximately 1 inch by 1 inch. FIG. 15a shows a new version of the battery cell shown in FIG. 15 and in particular a carbon nanotube anode produced by the methods of this invention. Referring specifically to FIG. 15a, numeral 31 is the cathode collector, numeral 32 is the anode collector and numeral 33 is the separator. More than one anode, more than one cathode, and more than one separator can be used to form a lithium ion battery and the components may be used as a flat sheet assembly or rolled into a cylinder. The final assembly is then placed in a container and contacted with the electrolyte solution. The cathode collector 31 is comprised of a coating 34 which contains the Li source, and the anode collector 32 is comprised of a carbon nanotube coating 35 on its surface. For these tests, the cathode coating providing the Li source in the battery was comprised of 86.5% wt. % LiCoO2, 4.5 wt. % lithium carbonate, 6 wt. % graphite, and 3 wt. % pVDF, and the anode was comprised of about 90 wt. % carbon nanotubes (grown directly on a UNS C195 copper alloy) and 10 wt. % pVDF. The cathode coating was applied by slurrying the solids in NMP solvent, applying to an aluminum foil, evaporating the solvent, and hot pressing (laminating). The pVDF was applied to the CNT coating by first dissolving the pVDF in NMP solvent, followed by evaporating the solvent and hot pressing (i.e., laminating). The two electrodes were separated by an ion permeable membrane 33, comprised of a 25 micrometer thick tri-layer microporous membrane of polypropylene-polyethylene-polypropylene (Celgard® 2325) manufactured by Celgard®. The membrane can be used as a separate sheet placed between the electrodes, or, one of the electrodes could be placed inside a bag or sleeve comprised of the membrane material. For this example, the cathode was placed inside a sleeve of the separator material prior to assembly into a battery. The Li ion battery circuit is completed by connected a charging source or load by connection means 36. The cells were discharged from 4.1V to 2.7V at a current of 0.500 mA using a Princeton Applied Research Model 362 Potentiostat/Galvanostat apparatus. They were charged at a constant voltage of 4.1V until the current reached a very low value (0.050 mA), and the cycle was then repeated. Each of the cells was cycled for ten to fifteen complete cycles, and the data was normalized according to the weight of the anode material. The capacities were twice as high as capacities of electrodes made with conventional activated carbon, and the capacities for both types of electrodes were within 8.5% through 15 cycles. The data is reported compared to activated carbon due to the non-optimization of our bench-top cell design, electrode layout, electrolyte composition, testing apparatus, charging methodology, and cathode preparation. However, all these non-optimized factors were kept constant throughout our tests with only the form of the carbon on the anode changing. Therefore, the improvement in capacity is thought to be due entirely to the CNTs.

### EXAMPLE 12

An air cooled heat sink configuration has also been designed, fabricated, and tested. The heat sink of the type depicted in FIG. 11 was fabricated from copper (CDA-706) and then a nanotube coating was grown on the convective heat transfer surface. The heat sink 15 contained eight fins 16, which were 0.700″ tall, 1.0″ wide, and fabricated with a uniform fin thickness and fin spacing of 0.066″. Other heat sink geometries could also have been used to demonstrate a similar benefit of nanotube coating of the surface. This particular configuration was arbitrarily selected.

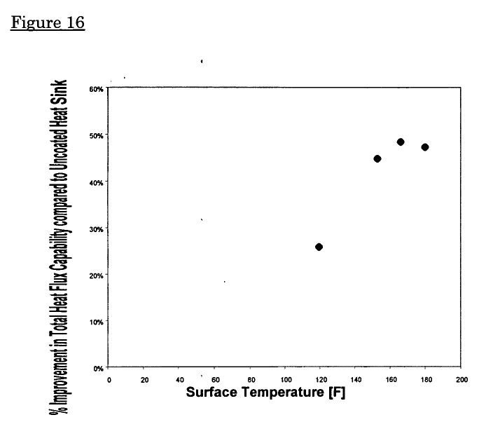

The nanotube coating was applied to one copper heat sink and its performance compared to an essentially identical untreated heat sink. FIG. 16 displays the improvement in the heat rejection capability for this arbitrarily selected 8-fin nanotube treated heat sink (compared to an otherwise identical uncoated heat sink). The improvement in performance of the coated heat sink, at a typical heat sink operating temperature of 70° C., is about 45%, which translates into a capability to reject 45% more heat or to lower the temperature difference for equivalent heat transfer by 45%.

### EXAMPLE 13

The alloys CDA 704 (91% Cu, ˜1.5% Fe, ˜5.5% Ni), Hastelloy G-30 (43% Ni, ˜30% Cr, ˜15% Fe, ˜5% Mo), Hastelloy C-276 (57% Ni, ˜16% Cr, ˜6% Fe, 16% Mo), and Incoloy MA956 (74% Fe, 5% Al, 20% Cr, 0.5% Y2O3) were pickled using methods adapted from ASTM method G1-03. Coupons measuring 0.45 inches by 1 inch were placed in a CVD furnace and coated with nanotubes. The weight gain on the materials due to carbon nanotube growth was on average 12, 8, 14, and 5 grams per square meter, respectively.

### EXAMPLE 14

A laminate composite was fabricated using a MA 956 alloy and a polyester-styrene resin and peroxide hardener. The carbon nanotube coated MA 956 alloy was dipped into a resin/hardener solution, removed, and allowed to cure.

### EXAMPLE 15

Carbon nanotubes and amorphous carbon were grown on a CDA 706 alloy coupon. We have found that, under certain combinations of carbon feedstock, time, and furnace temperature, a “felt” can be grown onto the metal substrates. Some of the resulting carbon layer was then removed, weighed, and subjected to a furnace open to air at 500° C. for 16 hrs. The final mass was weighed. Because amorphous carbon will oxidize to CO and CO₂ at temperatures of about 400-600° C., while nanotube carbon oxidizes at temperatures above about 650° C., we were able to estimate the percent of nanotubes in the “felt”. From our experiments, we estimated that the carbon “felt” comprised about 30% carbon nanotubes. This technique is also applicable to growing carbon nanotubes without the use of support materials and catalysts. The metal or metal alloy coupons could be reused in a production process to grow and harvest carbon nanotubes.

### EXAMPLE 16

A carbon nanotube coating was grown on a single-phase water-cooled cold plate (fabricated from CDA-706) as per Example 13 to demonstrate the side-by-side benefits of the nanotube coating, but this time for single-phase liquid cooling. When the heat sinks were cooled with 48.8° C. (120° F.) inlet water, and exposed to a 45 W heat load (operating in Laminar Flow, Re=95), the nanotube coated heat sink displayed a 132% increase in the overall heat transfer coefficient.

### EXAMPLE 17

Granules having mesh size of −12 of the metal alloy Fe_{0.85}Ni_{4.15}Mm, where Mm is a combination of La, Ce, Nd, and Pr, were placed in a CVD furnace and coated with carbon nanotubes. This alloy is commonly used for hydrogen storage. The CVD nanotube growth conditions were 900° C. for 2.5 hrs with 500 sccm hydrogen, 1000 sccm methane, and 20 sccm ethylene. Preceding this step, the materials was exposed to 5-500 sccm hydrogen at 900° C. for 15 minutes to remove and reduce impurities on the surface of the metal alloy. The weight of carbon nanotubes grown on the surface of the materials was 120 milligrams, or 1.4% by weight on the metal alloy. This process was also repeated for fine powders of the alloy, the powders produced by cycling the material between hydrogen and vacuum, a process which decrepitates metal hydride alloy materials.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1. Method, comprising producing a composite by contacting a metal: substrate with a feedstock to form nanotubes, and using the composite in devices for one of electrical energy storage and retrieval, gas adsorption and desorption, sensing, catalysis, heat transfer, fuel cells, solar collectors and medical prosthesis.

2. Method according to claim 1, wherein the device for electrical energy storage and retrieval is one of a battery electrode and an ultracapacitor electrode.

3. Method according to claim 2, wherein the metals comprising the metal substrate have an electrical resistivity of about no more than 9 microohms-cm.

4. Method according to claim 1, wherein the device for sensing is a chemical sensor.

5. Method according to claim 1, wherein the device for gas adsorption or desorption is one of hydrogen storage and a catalysis device including a catalytic converter or a cracking catalyst for oil production.

6. Method according to claim 1, wherein the device for heat transfer is selected from the group consisting of heat sinks, heat pipes, heat exchangers, spray cooling apparatus, single-phase convection apparatus and two-phase convection apparatus.

7. Method according to claim 6, wherein the metals comprising the metal substrate have a thermal conductivity of at least 90 W/m-K.

8. Method according to claim 1, wherein the feedstock is a hydrocarbon feedstock.

9. Method according to claim 1, wherein the nanotubes are carbon nanotubes.

10. Method according to claim 1, wherein the producing of the composite includes
(a) cleaning the metal substrate;
(b) introducing the metal substrate into a furnace;
(c) heating the metal substrate;
(d) contacting the feedstock with the metal substrate to form the nanotubes; and
(e) optionally subjecting the metal substrate to one of air, oxygen and plasma to remove amorphous carbon.

11. Method according to claim 10, wherein the metal substrate is a metal alloy.

12. Method according to claim 10, wherein said furnace is a CVD furnace heated to between about 500° and 1200° C.

13. Method according to claim 10, wherein said feedstock comprises compounds selected from the group consisting of ethylene, methane, propane, acetylene, carbon monoxide, methanol, ethanol, benzene, toluene and xylene.

14. Method according to claim 1, wherein the metal substrate comprises at least one metal selected from the group consisting of Cu, Al, Be, Co, Cr, Fe, Hf, Ir, Mn, Mo, Nb, Ni, Os, Pb, Pd, Pt, Rh, Ru, Sb, Ta, Ti, V, Y, Zr, and oxides thereof.

15. Method according to claim 1, wherein the nanotubes are one of single-walled and multi-walled nanotubes.

16. Method according to claim 15, wherein the nanotubes are perpendicularly oriented.

17. Method, comprising directly coating a surface of a copper alloy body with carbon nanotubes, and using the body to exchange heat between a gas or liquid.

18. Method according to claim 17, wherein a hydrocarbon feedstock is used in the direct coating.

19. Method, comprising directly coating a surface of a copper alloy body with carbon nanotubes, and using the body to evaporate and condense fluids.

20. Method according to claim 19, wherein a hydrocarbon feedstock is used in the direct coating.

21. Method, comprising directly coating a surface of a metal alloy body with nanotubes to form a composite, and optionally coating the coating with at least one of a wear-resistant material, a corrosion-resistant material, a self-lubricant material, a low-friction material and a combination thereof.

22. Method, comprising directly coating a surface of a metal alloy body with carbon nanotubes, and using the body in a corrosive environment.

23. Method according to claim 21, wherein the metal alloy is one of Allac®, Nickelvac, Carpenter, Elgiloy®, Haynes®, Stellite®, Stoody®, Tribaloy®, Hastelloy®, INCONEL®, NIMONIC™, NILO™, Allegheny Ludlum, Monel™, INCO™, Deloro®, Osprey Metals, INCOLOY®, Nichrome™, and Super Alloys, as well as other alloys based on stainless steel, carbon steel, copper (UNS series 100, 600, 700, 800 and 900), nickel, brass, and titanium.

24. Method, comprising directly coating a surface of a copper alloy body with carbon nanotubes, and using the surface for spray cooling applications.

25. Method, comprising directly coating an inner surface of a copper alloy body of selected configuration or copper alloy wicking material with carbon nanotubes, and using the body or wicking material for heat pipe applications.

26. Method, comprising directly coating a copper alloy body surface with carbon nanotubes, and using the surface for one of a battery electrode and an ultracapacitor electrode.

27. Method, comprising directly coating a surface of a copper alloy body with carbon nanotubes, and using the body as an implantable medical device or prosthesis.

28. Method, comprising directly coating a surface of a copper alloy body with carbon nanotubes, and using the body as a heat sink for electronics cooling.

29. Method, comprising directly coating a copper alloy with carbon nanotubes to form a composite, and coating the composite with a thermoset or thermoplastic polymer.

30. Method, comprising directly coating a surface of a metal alloy body with carbon nanotubes.

31. Method according to claim 30, wherein the metal alloy body is selected from a group of metal alloys consisting of Allvac®, Nickelvac, Carpenter, Elgiloy®, Haynes®, Stellite®, Stoody®, Tribaloy®, Hastelloy®, INCONEL®, NIMONIC™, NILO™, Allegheny Ludlum, Monel™, INCO™, Deloro®, Osprey Metals, INCOLOY®, Nichromem™, and Super Alloys, as well as other alloys based on stainless steel, carbon steel, copper (UNS series 100, 600, 700, 800 and 900), nickel, brass, and titanium.

32. Method according to claim 30, wherein the metal alloy body is selected from a group of metal alloys consisting of two or more elements in the following weight percentage ranges: Cu from 0% to about 95%, Fe from 0% to about 76%, Ni from 0% to about 78%, Mo from 0% to about 85%, Y2O3 from 0% to about 1%, Mn from 0% to about 15%, Zn from 0% to about 39%, Cr from 0% to about 52%, Co from 0% to about 63%, Pb from 0% to about 15%, Sn from 0% to about 13%, Al from 0% to about 12%, Si from 0% to about 4%, W from 0% to about 16%, Ti from 0% to about 98%, Ag from 0% to about 50%, Zr from 0% to about 10%, and other minor constituents.

33. Method, comprising directly coating a substrate with carbon nanotubes, and removing the carbon nanotubes for reuse thereof.

34. A continuous coating process, comprising
(a) heating a metal alloy substrate fed continuously into and out of a CVD furnace;
(b) introducing one or more feedstock gases into the CVD furnace;
(c) growing nanotubes on the substrate while substrate is conveyed through the furnace;
(d) optionally providing different heating zones and gas compositions along the conveyed length of the substrate through the furnace;
(e) cooling the substrate to ambient temperature and pressure.

35. Process according to claim 34, wherein the metal alloy is a copper alloy.

36. Process according to claim 34, wherein the feedstock gases are compounds.

37. A copper alloy substrate-carbon nanotube composite made by
(a) cleaning the copper alloy substrate;
(b) introducing said substrate into a furnace;
(c) heating the substrates and flowing hydrocarbon vapors and optionally hydrogen thereover, and
(d) optionally subjecting the substrate to one of air, oxygen and plasma to remove amorphous carbon.

38. Composite according to claim 37, wherein substrate is introduced on a continuous basis.

39. Composite according to claim 37, wherein the furnace is a CVD furnace which is heated to between about 500° and 1200° C.

40. Composite according to claim 37, wherein the hydrocarbon vapors are combinations of ethylene, methane and hydrogen.

41. Composite according to claim 37, wherein the copper alloy substrate contains at least one additional metal selected from the group consisting of Al, Be, Co, Cr, Fe, Hf, Ir, Mn, Mo, Nb, Ni, Os, Pb, Pd, Pt, Rh, Ru, Sb, Ta, Ti, V, Y, Zr, and oxides thereof.

42. Composite according to claim 37, wherein the carbon nanotubes are single-walled or multi-walled nanotubes.

43. Composite according to claim 37, wherein the copper alloy is selected from the group consisting of UNS series 100, 600, 700, 800 or 900 alloys.

44. Composite according to claim 37, wherein said hydrocarbon vapors comprise compounds selected from the group consisting of ethylene, methane, propane, acetylene, carbon monoxide, methanol, ethanol, benzene, toluene and xylene.

45. Carbon nanotubes produced by
(a) growing carbon nanotubes on a metal or metal alloy substrate, and
(b) removing the carbon nanotube coating from the substrate.

46. Method, comprising directly coating a metal alloy substrate with nanotubes, and applying a polymeric coating thereover.

47. Method according to claim 46, wherein the nanotubes are compounds selected from the group consisting of BN, WS2, V2O5, MoS2, SiO2, Al₂O₃ and ZrO2.

48. Method according to claim 46, wherein the nanotubes are carbon.

49. Method according to claim 1, wherein the nanotubes are compounds selected from the group consisting of BN, WS2, V2O5, MoS2, SiO2, Al₂O₃ and ZrO2.

50. Method according to claim 1, wherein the nanotubes are carbon.

51. Method according to claim 1, wherein the nanotubes constitute substantially all of the coating material.

52. Method according to claim 21, wherein the nanotubes comprise a combination of carbon and inorganic nanotubes.

53. Method according to claim 2, wherein the battery electrode optionally comprises a polymer binder.

54. Method according to claim 53, wherein the polymer binder is poly(vinylidene fluoride) or co-polymers thereof.

55. Method according to claim 53, wherein the battery electrode comprising an optional polymer binder is pressed prior to assembly into a battery.

56. Method according to claim 2, wherein the battery is a lithium ion battery comprising at least one said battery electrode, at least one cathode, and at least one separator membrane.

57. Method according to claim 56, wherein said at least one battery electrode is coated on both sides with carbon nanotubes and is provided optionally with polymer binder.

58. Method according to claim 1, wherein the feedstock comprises at least one hydrocarbon compound, and at least one other compound selected from the group consisting of ethanol, water, ammonia, argon, and nitrogen.

59. Method according to claim 2, wherein the battery electrode operates between a voltage of about 2.5 V and a voltage of about 4.3V.
